(19) United States
(12) Patent Application Publication
(10) Pub. No.: US 2026/0311018 A1
(43) Pub. Date: Oct. 8, 2026

(54) SUPERCONDUCTING PHASE SHIFTER FOR PRECISE CRYOGENIC QUANTUM CONTROL THROUGH A CLASSICAL NODE

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/045,504

(22) Filed: Feb. 4, 2025

(51) Int. Cl. G06N 10/40; G01R 33/035; H01P 1/18

(52) U.S. Cl. CPC G06N 10/40; G01R 33/0354; H01P 1/182

(57) ABSTRACT

The technology described herein is directed towards a superconducting phase shifter with phase shift controlled via radio-frequency superconducting quantum interference devices (RF-SQUIDs). The phase shifter incorporates a quadrature hybrid coupler that divides an incoming microwave signal into microwave signals to reflective loads of the phase shifter. The inductances of the reflective loads are tuned by voltages/current levels applied to respective control lines coupled to RF-SQUID sets inductively coupled to inductors of the reflective loads. The reflected instances constructively interfere to output a finely (voltage) controlled phase-shifted signal. In one implementation, the superconducting phase shifter can be monolithically integrated on the same chip at the qubits. The superconducting phase shifter can be controlled by a classical computing device that can monitor a qubit's phase-related information, can adjust the phase control system, via the superconducting phase shifter in real time based on any detected phase drift and/or phase noise.

### BACKGROUND

Microwave phase shifters are devices that adjust the phase of microwave photons, and are thus used in quantum computing, particularly in systems based on superconducting qubits. The phase of microwave signals is finely tuned by a phase shifter to ensure precise control over qubit rotations, which are fundamental operations in quantum gates. Phase shifters are also used when performing controlled-phase gates, a type of quantum gate that operates by inducing a phase shift in the target qubit conditional on the state of the control qubit. Microwave phase shifters also play a role in multiqubit operations, such as CNOT (Controlled NOT) and CZ (Controlled-Z) gates, providing phase alignment to maintain coherence and minimize errors. Additionally, quantum error correction and the sensitive readout of qubit states rely on microwave phase shifters.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example reflective-type phase shifter suitable for use with quantum hardware, with signal input from a classical microwave source and phase-shifted output directed to the qubits, in accordance with various example embodiments and implementations of the subject disclosure.

FIG. 2 is a representation of the layout of the example reflective-type phase shifter of FIG. 1, showing radio frequency-superconducting quantum interference devices (RF-SQUIDs) for tunable phase shift control and reflective loads incorporating capacitors and inductors, in accordance with various example embodiments and implementations of the subject disclosure.

FIG. 3 is a three-dimensional representation of the layout of the example reflective-type phase shifter of FIGS. 1 and 2, highlighting a quadrature coupler, crossovers, and placement of the RF-SQUIDs, in accordance with various example embodiments and implementations of the subject disclosure.

FIG. 4 is a three-dimensional view representation of the layout of the example reflective-type phase shifter of FIGS. 1-3, including zoomed in views of parts of the layout, in accordance with various example embodiments and implementations of the subject disclosure.

FIG. 5 is an example multilayer stack designing for the example phase shifter, in accordance with various example embodiments and implementations of the subject disclosure.

FIG. 6 is a plot of simulated relative phase shift versus frequency for one example phase shifter, showing phase shift tunability with sourced current ranging from zero milliamps (mA) to four mA, in accordance with various example embodiments and implementations of the subject disclosure.

FIG. 7 is a block diagram representation of an example a hybrid classical-quantum system in which a phase shifter is deployed in a dilution refrigerator before a qubit chain to add defined phase shift from a classical (non-quantum) computing device/node, in accordance with various example embodiments and implementations of the subject disclosure.

FIGS. 8 and 9 depict an example hybrid classical-quantum system for controlling and measuring qubit operations, including via selectively applied variable phase shifts to qubits via a cryogenic phase shifter, in accordance with various example embodiments and implementations of the subject disclosure.

FIG. 10 is a conceptual representation of a quantum computer including a dilution refrigerator with qubits and a cryogenic phase shifter operating at qubit temperatures, in accordance with various example embodiments and implementations of the subject disclosure.

FIGS. 11 and 12 comprise a flow diagram showing example operations related to controlling a phase shifter to apply a defined phase shift to a microwave signal, based on applying voltages to control lines, in accordance with various example embodiments and implementations of the subject disclosure.

### DETAILED DESCRIPTION

The technology described herein is generally directed towards a superconducting phase shifter with precise phase control, based on radio frequency-superconducting quantum interference devices (RF-SQUIDs). The phase shifter incorporates a quadrature hybrid coupler that divides an incoming microwave signal into microwave signals that are reflected as reflected instances by reflective loads of the phase shifter, in which the respective inductances of the reflective loads are tuned by respective voltages applied to respective control lines coupled to respective RF-SQUID sets. The reflected instances, with their reflected phase shifts determined by the respective tuned inductances, constructively interfere to output a finely (voltage) controlled phase-shifted signal.

The superconducting phase shifter, operating at cryogenic temperatures (e.g., T~10 milliKelvin (mK) or even lower, e.g., T=<4 K), is deployed between the photon source and the qubit chain. In one implementation, the superconducting phase shifter can be monolithically integrated on the same chip at the qubits and is optimized for operation at extremely low cryogenic temperatures of 2 mK. The superconducting phase shifter applied to cryogenic microwave circuits ensures signal integrity, and preserves qubit coherence and the fidelity of quantum operations.

In one implementation, the superconducting phase shifter is controlled by a classical computing device. The classical computing device can operate as a monitoring system to mitigate phase noise errors in quantum gate operations. The classical control node monitors the phase, detecting any deviations or noise-induced errors, and can adjust the phase control system, via the superconducting phase shifter, in real time, based on any detected phase drift and/or phase noise. This significantly reduces phase drift and noise, ensuring higher stability and fidelity of qubit operations. By placing the phase shifter in close proximity to the qubits (e.g., T≈mK), or even monolithically integrated on a qubit chip, the system minimizes thermal noise and maximizes coherence during quantum gate operations, thus improving overall quantum computation performance.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics, and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

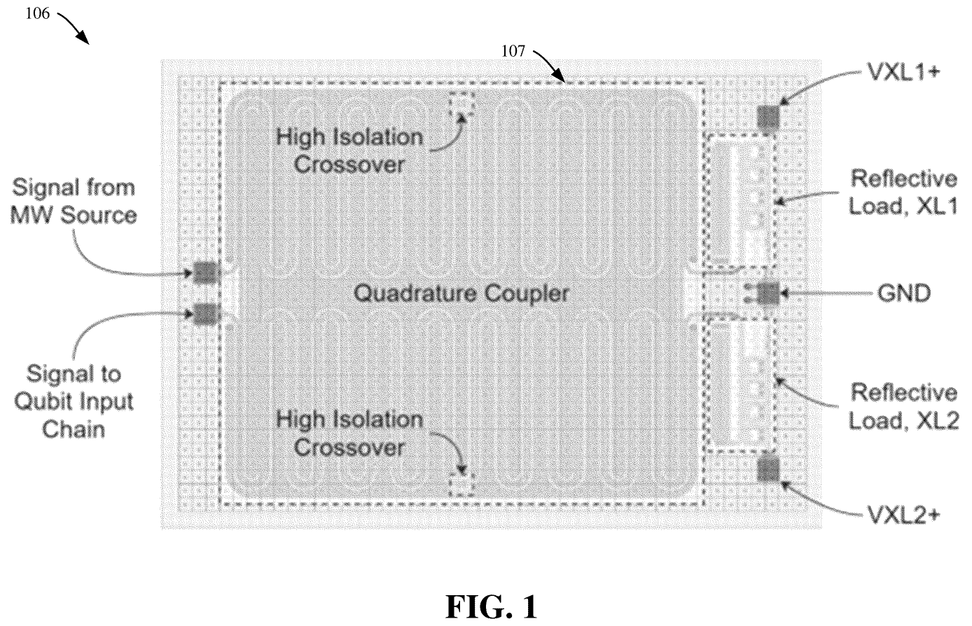

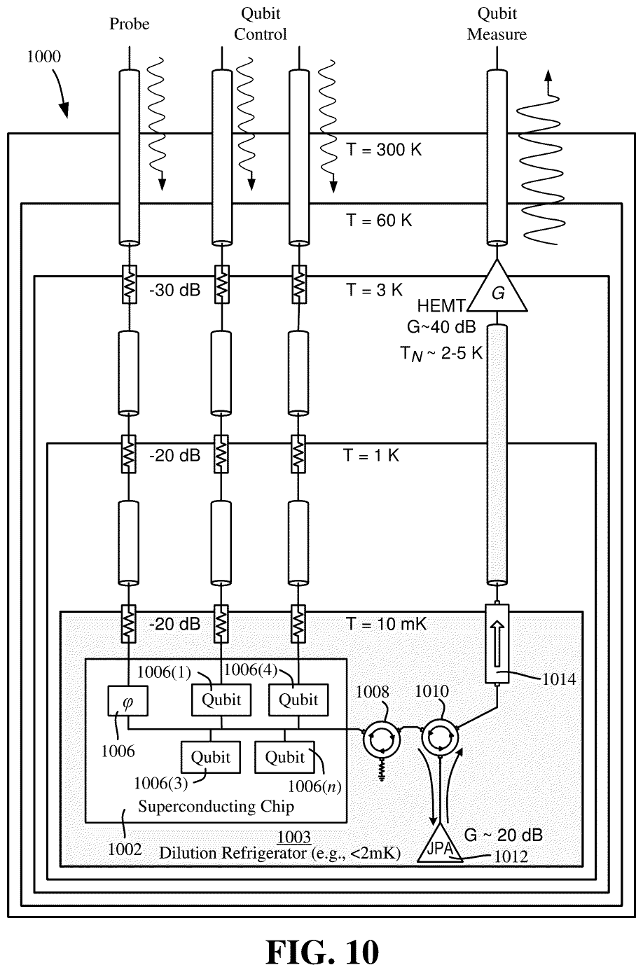

FIG. 1 is a top view of a suitable microwave phase shifter 107 (FIGS. 1-5) designed for use at cryogenic temperatures. In general, the phase shifter 107 described herein operates as a phase shifter with precise phase control based on RF-SQUID-based superconducting. The example device can be deployed in a dilution refrigerator, and indeed, as in FIG. 10, can be monolithically integrated on the same chip as the qubits, e.g., optimized for operation at extremely low cryogenic temperatures of around 2 mK.

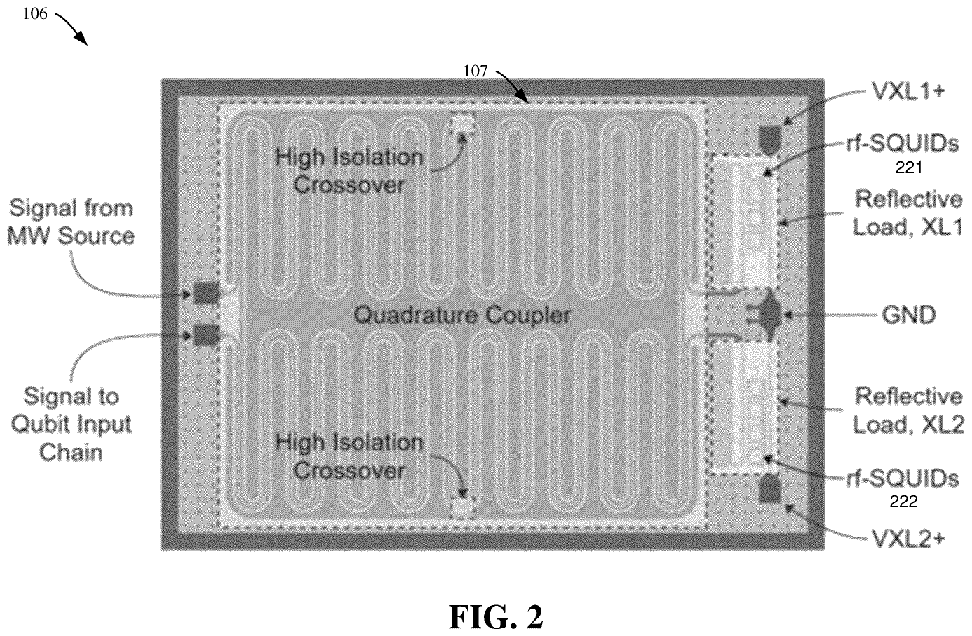

Described herein is a reflective-type topology for the example phase shifter 107 that incorporates a hybrid coupler 107 and two (e.g., identical) reflective loads XL1 and XL2, as shown in FIGS. 1 and 2. The hybrid coupler 107, also known as quadrature coupler, divides and can combine microwave signals. Note that typically the hybrid coupler is a ninety degrees (90°) hybrid coupler that divides an incoming microwave signal into a first, non-phase-shifted instance of the microwave signal, and a second, phase-shifted instance of the microwave signal that is 90° degrees phase shifted relative to the first, non-phase-shifted instance.

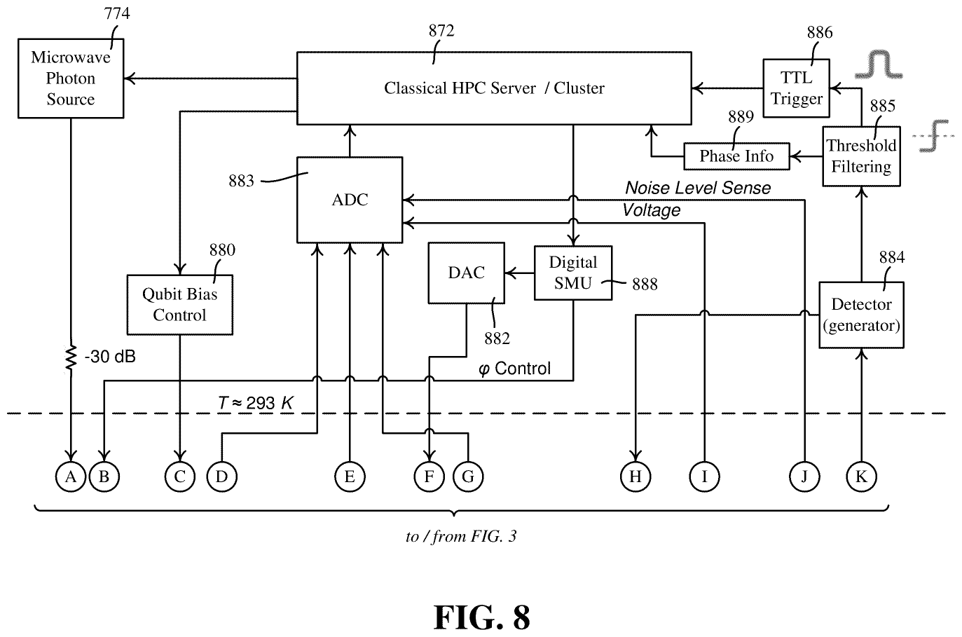

The example phase shifter design shown in FIGS. 1-4 employs a tandem coupled line approach for the hybrid coupler 107, using a coplanar waveguide (CPW) structure. Such a CPW-based hybrid coupler has two parallel coupled lines placed side by side, with high-isolation crossovers routed through a separate superconducting layer using interlayer vias. Such multilayer fabrication ensures that the crossovers of the tandem structure are isolated from the coupled lines, ensuring large isolation. The input microwave (MW) signal comes from a classical computing device (e.g., FIG. 8) and the output is directed towards the qubits.

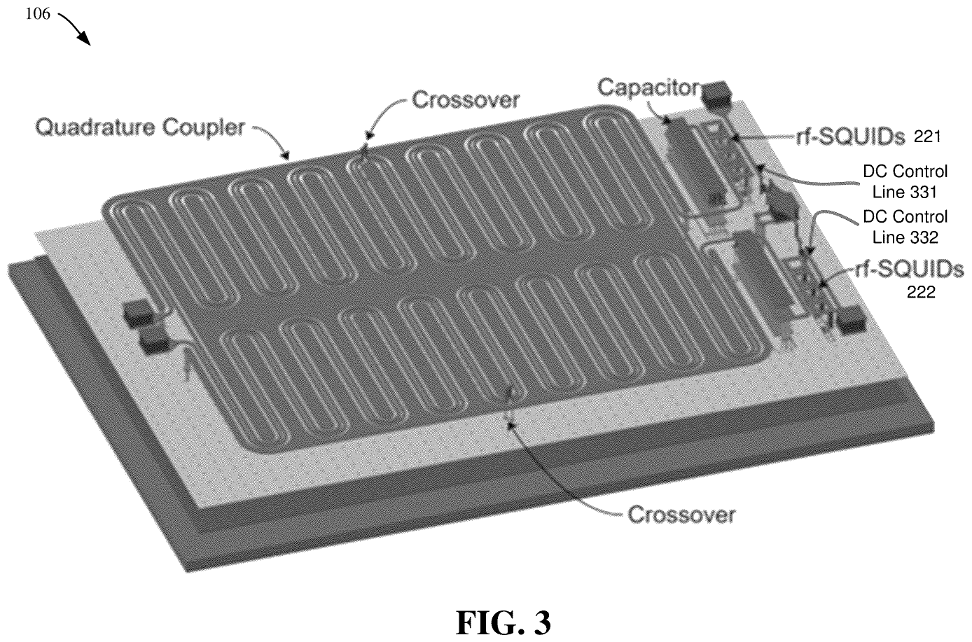

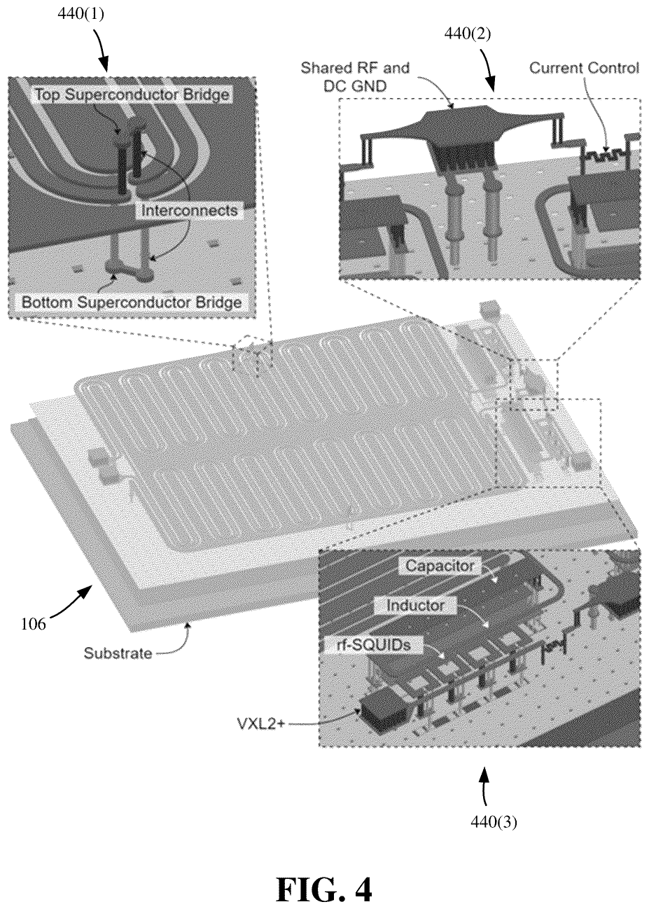

As shown in the three-dimensional (3D) views of FIGS. 3 and 4, each reflective load (e.g., XL1) is designed using a series connection of a metal-insulator-metal (MIM) capacitor and a microstrip inductor, with the microstrip inductor grounded at its free end. The microstrip is designed to ensure a characteristic impedance of fifty ohms relative to the ground plane. As shown in FIGS. 2 and 3, sets of RF-SQUID 221 (for the reflective load XL1) and 222 (for the reflective load XL2) offer variable inductance when subjected to external magnetic flux from a nearby current line 331 and 332, respectively, (FIG. 3), and are integrated alongside (and thereby inductively coupled to) the respective microstrip inductors of the respective reflective loads XL1 and XL2. These RF-SQUID sets 221 and 222 provide tunability for the load impedance and phase shift. As the inductance of a respective RF-SQUID set changes, so does the inductance of the respective microstrip inductor inductively coupled thereto, modulating the phase shift.

The microwave signal from the microwave source applied at the input port (FIGS. 1 and 2) of the hybrid coupler 107 undergoes a phase shift, which is then obtained at the output port and sent to qubit input chain. More particularly, the microwave signal at the input port is divided equally into two instances with 90° phase difference between them. Each of these split signals goes to a reflective load. The change in inductance in each reflective load determines the phase at the output port from the hybrid coupler because the signals reflected from each reflective load interfere constructively at the output port. Hence, the phase shift is controlled by the current provided to the DC (direct current) control current line, which tunes the magnetic flux threading each RF-SQUID loop, and thereby the inductance of the inductors of each reflective load, modulating the phase shift between the input and output signals.

The respective DC current lines run parallel to the respective RF-SQUID sets 221 and 222, and the current in the line is controlled by the voltage applied at terminals VXL1 and VXL2 for reflective loads XL1 and XL2, respectively. These lines share a common ground. Each tunable reflective load's impedance, primarily determined by its imaginary component XL, and the reflection coefficient I′, are influenced by the corresponding RF-SQUID set's inductance, which is controlled via the applied voltage.

The 3D view of the layout in FIG. 4 highlights some of key details of the design. A first zoomed-in section 440(1) highlights the interconnects (bridges) in the design that are routed from different superconducting layers in the fabrication stack, that is, above or below the primary layer of the hybrid coupler. A second zoomed-in section 440(2) shows the common ground plane for the two control lines for the RF-SQUIDs. In this example, each control line for controlling the inductance of an RF-SQUID set includes a current controlled device (the meandering conductor) that does not let the current exceed a certain level in the line. This is a protection device, as very high levels of current on the line lead to higher magnetic flux threading the RF-SQUIDs, which can damage their operation. In the example design, monolithically integrated current control devices in-built in the circuit is used, as shown in the zoomed-in section 440(2).

A third zoomed-in section 440(3) illustrates the arrangement of the MIM capacitors, microstrip inductors, and RF-SQUID sets in each reflective load.

To derive the expression for the change in inductance of the microstrip inductor (in the reflective load) when coupled with RF-SQUIDs, consider a microstrip unit cell, which in an equivalent circuit includes a shunt capacitance Cₘ and series inductance Lₘ, coupled to a superconducting loop with inductance L_{sq} and Josephson Junction (JJ) with inductance Lⱼ. The coupling between Lₘ and L_{sq} is defined by mutual coupling M₁ and coupling coefficient K₁. Additionally, a microstrip control transmission line, monolithically integrated on-chip, runs parallel to the RF-SQUIDs. The unit inductance of this control microstrip transmission line Lc couples to the SQUID loop inductance L_{sq} with mutual inductance M₂ and coupling coefficient K₂.

$${K}_{1}^{2} = \frac{{M}_{1}^{2}}{{L}_{s q} {L}_{c}} ; {K}_{2}^{2} = \frac{{M}_{2}^{2}}{{L}_{s q} {L}_{c}} \qquad ( 1 )$$

The control current i_{dc} applied to the control line generates a magnetic field around the microstrip top conductor, inducing a geometrical flux φₑₓₜ in the SQUID loop:

$${ϕ}_{ext} = {M}_{2} {i}_{dc} \qquad ( 2 )$$

A circulating current i_{sq} is induced in the SQUID loop to screen this flux, due to flux quantization condition, leading to the total flux φ_{sq} in the loop:

$${ϕ}_{s q} = {ϕ}_{ext} + {L}_{s q} {i}_{s q} \qquad ( 3 )$$

The circulating supercurrent depends on the critical current I_{c} of the JJ and the total flux in the SQUID loop:

$${i}_{s q} = - {I}_{c} sin \frac{2 π {ϕ}_{s q}}{{ϕ}_{0}} \qquad ( 4 )$$

where φ₀ is the flux quantum (φ₀=2.0679×10⁻¹⁵ Wb) and I_{c} is determined by the area of the junction A and the current density J_{c} of the junction. The behavior of the SQUID is characterized by the screening parameter of RF-SQUID given by:

$$β = \frac{2 π {L}_{s q} {I}_{c}}{{ϕ}_{0}} \qquad ( 5 )$$

For this application, the condition β<1 is satisfied, and the internal flux in the SQUID increases monotonically with the external flux φₑₓₜ.

SQUID inductance is a combination of the junction inductance and the inductance of the superconducting loop. The effective inductance controlled by modulating the magnetic flux threading the junction loop can be obtained as:

$${L}_{eff} = \frac{d {ϕ}_{ext}}{{di}_{s q}} \qquad ( 6 )$$

Differentiating equation (3) with respect to iₛ

$$\frac{d {ϕ}_{ext}}{d {i}_{s q}} = - {L}_{s q} + \frac{1}{d {i}_{s q} / d {ϕ}_{ext}} \qquad ( 7 )$$

Differentiating equation (4) with respect to φₛ

$$\frac{d {i}_{s q}}{d {ϕ}_{ext}} = - \frac{2 π {I}_{c}}{{ϕ}_{0}} cos ( \frac{2 π {ϕ}_{s q}}{{ϕ}_{0}} ) \qquad ( 8 )$$

Combining equations (5), (6), (7) and (8),

$${L}_{eff} = {L}_{s q} + \frac{{L}_{s q}}{β cos ( 2 π {ϕ}_{s q} ) / {ϕ}_{0}} \qquad ( 9 )$$

$${L}_{eff} = {L}_{s q} + {L}_{j} \qquad ( 10 )$$

where Lⱼ is the junction equivalent inductance.

$${L}_{j} = \frac{{L}_{s q}}{β cos ( 2 π {ϕ}_{s q} ) / {ϕ}_{0}} \qquad ( 11 )$$

The effective inductance of the microstrip inductor

$${L}_{m}^{′}$$

coupled to the SQUID is influenced by the change in inductance from the RF-SQUIDs and the level of mutual coupling between the inductive microstrip and the four RF-SQUIDs.

$${L}_{m}^{′} = {L}_{m} [ 1 - \frac{{K}_{1}^{2} {L}_{s q}}{{L}_{j} + {L}_{s q}} ] = {L}_{m} [ 1 - \frac{{K}_{1}^{2}}{1 + ( \frac{1}{β} cos ( \frac{2 π {ϕ}_{s q}}{{ϕ}_{0}} ) )} ]$$

In the reflective load design, the inductor L is connected in parallel with a capacitor C, with reactance X_{L} and X_{C}, respectively. The tunability in the inductance of the reflective load leads to a corresponding change in the phase of the load's reflection coefficient, enabling precise control over the phase shift.

$${X}_{L} = {ω}_{0} L ; {X}_{C} = - \frac{1}{{ω}_{0} C}$$

The tunability in the inductance of the reflective load leads to a corresponding change in the phase of the load's reflection coefficient, enabling precise control over the phase shift.

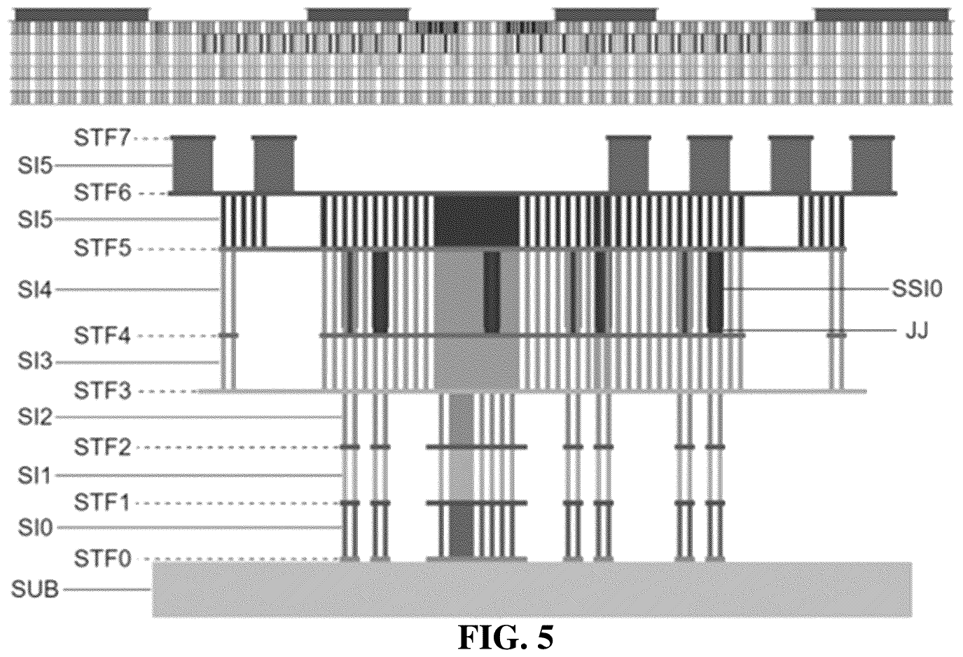

FIG. 5 shows a multilayer fabrication stack cross-section including multiple superconducting thin films (STF) connected using superconducting interconnects (SI), a short SI (SSI), current controlling resistor, and Josephson Junctions (JJ). Taking advantage of the multiple superconducting layers, the respective MIM capacitors in one implementation of the design use Josephson multiple layers.

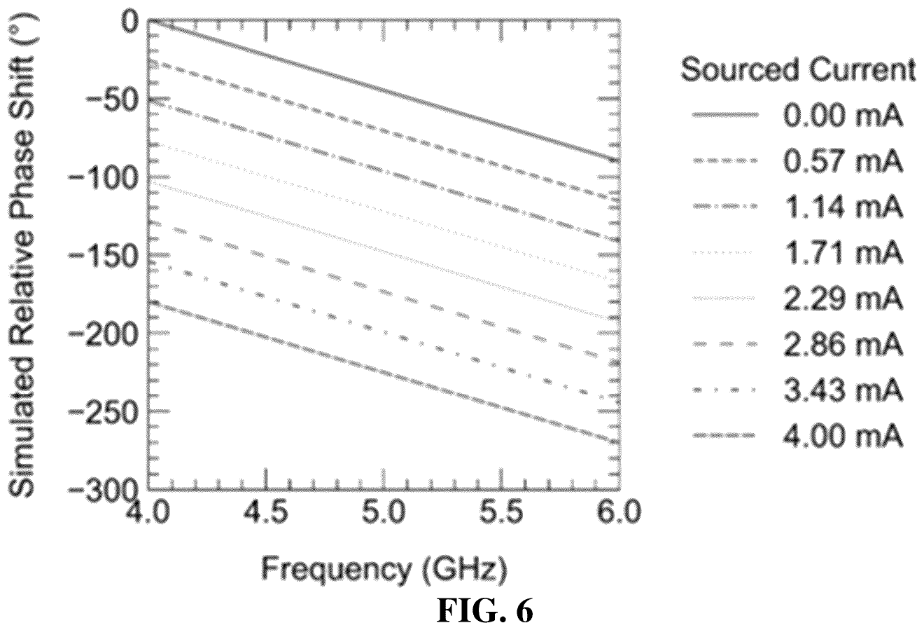

The plot in FIG. 6 illustrates the simulated relative phase shift of the example phase shifter 504 as a function of frequency, with different curves representing various sourced current levels from 0 mA to 4 mA. The plot demonstrates the phase tunability of the design, with the RF-SQUIDs providing fine control over the phase shift based on the current applied to them.

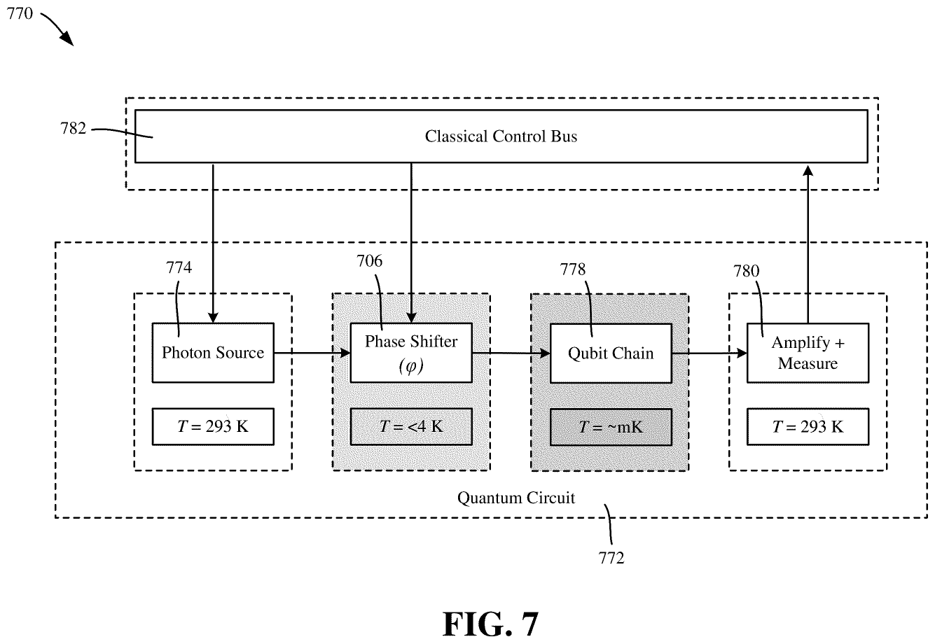

FIG. 7 is a generalized representation of an example hybrid classical-quantum system 770 that includes a quantum circuit 772 in which a photon source 774, phase shifter 704, qubit chain 778, and measurement setup (block 780) interact with the benefit of intermediate phase control as described herein. Note that this is in contrast to existing quantum circuits/systems, in which there is no phase control, making the qubits vulnerable to phase noise, thermal drift, or other forms of signal degradation; indeed, any misalignment in the phase of the signals can lead to errors in qubit manipulation, reducing gate fidelity.

The photon source 774 generates the microwave signals used to manipulate qubits, as controlled by the computing device (the control bus 782 of which is shown in FIG. 7); the temperature at this stage is room temperature (e.g., around 293 K). The phase shifter 706 operates at cryogenic temperatures (below 4 K in this example). The phase shifter 706 adjusts the phase of the microwave signals before they interact with the qubits of the qubit chain 778. The placement at cryogenic temperatures helps reduce phase drift caused by thermal noise.

The qubit chain 778 includes qubits that are maintained at extremely low temperatures (millikelvin range) to ensure their stability/coherence during quantum gate operations. The signals from the photon source interact directly with the qubits, manipulating their quantum states. After interacting with the qubits, the signal is amplified and measured (block 780) at room temperature; the amplified and measured signals are processed at room temperature by the classical computing device.

As set forth herein, maintaining phase coherence facilitates the stable operation of qubits during quantum gate operations. The cryogenic phase shifter 706 deployed between the photon source 777 and the qubit chain 778 facilitates the control and adjustment of the phase of the microwave signals that interact with the qubits. The placement of the phase shifter at cryogenic temperatures (T=<4 K) ensures the system is less susceptible to thermal noise, which can induce phase drift and cause errors in qubit operations. The photon source 774, operating at room temperature (T=293 K), generates microwave signals that pass through the cryogenic phase shifter 706 before reaching the qubits/qubit chain 778, which can be housed in an even colder environment (T≈mK) to maintain coherence; (note that the phase shifter can be maintained on the same chip in which the qubits are integrated, as in FIG. 10).

Further, the integration of the classical computing device (control node) monitors the phase of the signals in real time, to detect any phase noise errors or deviations that arise due to external environmental factors or hardware imperfections. Because quantum gate operations are extremely sensitive to such phase variations, the classical computing device compares the phase of the incoming signals as measured and flags any discrepancies (phase deviations) from what the phase shift should be without noise errors or the like. Upon detecting phase deviations, the control node dynamically adjusts the phase shifter 706 to correct the signal's phase before it interacts with the qubit chain, thereby minimizing the impact of phase noise on qubit operations.

Note that temperature control is a significant part of the quantum portion of the system, as different components operate at significantly different temperature levels to minimize noise and maintain coherence. The quantum processor operates at extremely low temperatures, with the qubit chain at 10 mK or below, and the signal amplifier at 30 mK. These temperatures maintain superconductivity and prevent thermal noise from disrupting the delicate quantum states. The flux sensing and phase control lines that interact with the qubits are also cooled down to 1 K to ensure minimal noise and stable control of the quantum operations. The classical control components, such as the microwave photon source, SMU, ADC, DAC, and HPC cluster, operate at room temperature (around 293 K). These components handle the classical data processing and control signals that drive the quantum system.

Via the phase control and classical monitoring feedback loop, the system effectively mitigates phase noise, ensuring that the signals interacting with the qubits are phase aligned and coherent throughout the gate operations. The cryogenic placement of the phase shifter minimizes thermal noise and drift, further enhances the system's ability to maintain phase coherence. The combination of real-time phase control and error monitoring by the classical node ensures that qubits remain stable during computation, resulting in higher-fidelity quantum gate operations and improved overall performance of the quantum system. The technology described herein thus overcomes a significant challenge in quantum computing, namely preserving qubit coherence and reducing phase-related errors during critical operations.

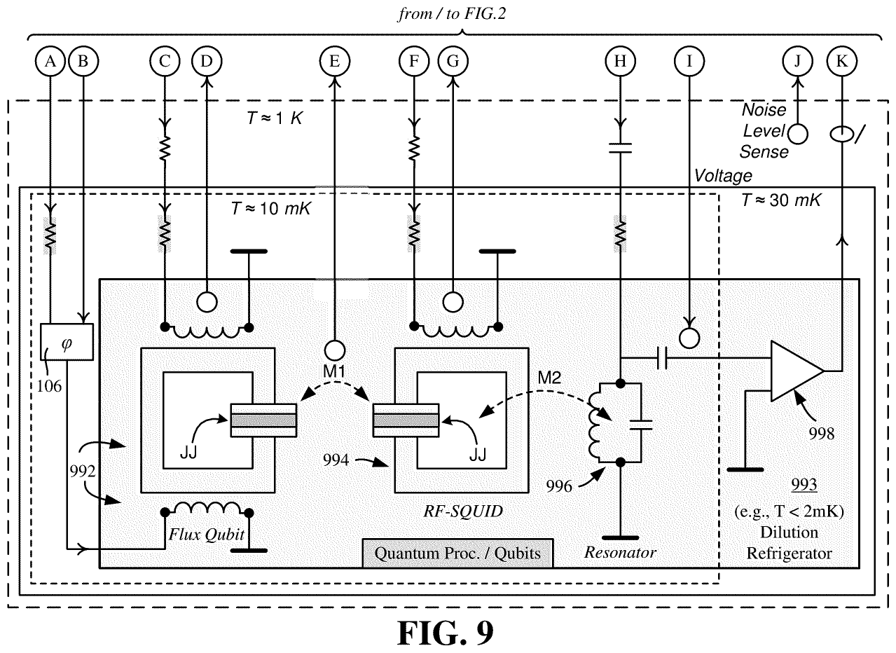

FIGS. 8 and 9 comprise a block diagram representation of an example quantum processor measurement and control setup/environment, in which qubit control and readout is facilitated by integrating a classical high-performance computing server/cluster 872 (FIG. 8) with a quantum computing system having a quantum processor and qubits 992 (FIG. 9) near the base plate of a dilution refrigerator 993, on the order of 2 mK.

The representation of FIG. 9 thus shows an example architecture of a quantum system with a focus on cryogenic control and signal processing. The overall system 770 (e.g., summarized in FIG. 7) integrates classical control components (FIG. 8) and quantum hardware (FIG. 9) to ensure the proper manipulation and measurement of qubits, with an emphasis on temperature management to maintain the coherence of quantum operations. As generally shown in FIG. 9, the quantum hardware is housed within the dilution refrigerator 993, ensuring ultra-low temperatures for stable qubit operations. In one implementation, the quantum portion (FIG. 9) of the hybrid system 770 (FIG. 7) operates with a combination of flux qubits, RF-SQUIDs, and a resonator, each contributing to the manipulation and control of quantum states.

In general, a flux qubit is a type of qubit that operates based on superconducting loops in which the current can circulate in both clockwise and counterclockwise directions, representing quantum superposition. The qubit (e.g., 992) is housed at a temperature of 10 mK or below (e.g., 2-4 mK), which helps maintain coherences and prevent decoherence due to thermal noise.

The RF-SQUIDs are superconducting circuits used to control the coupling between qubits. The RF-SQUIDs allow manipulation of quantum states by providing a tunable inductive coupling between the qubits. The Josephson junctions (JJ) in the RF-SQUIDs enable quantum tunneling, which is a core part of quantum operations in superconducting qubits. The magnetic interaction between the RF-SQUIDs (represented by M1), and between the RF-SQUID 994 and resonator 996 (represented by M2), can adjust the energy levels and state transitions of the qubits.

The resonator 996 is coupled to the qubits, providing a device to read out the qubit states. By measuring the resonance frequency shifts, the state of the qubits can be inferred, allowing for quantum state measurements. After interacting with the qubits, the signal is passed through a cryogenic amplifier 998, e.g., operating at around 30 mK. Amplifying the signal in such a low-temperature environment ensures that noise is kept to a minimum before the signal is sent for classical processing. The amplifier 998 helps to boost the weak quantum signals for subsequent measurement without introducing significant noise that could affect accuracy.

As shown in FIG. 8, the example classical (non-quantum) portion of the hybrid system 770 (FIG. 7) includes the microwave photon source 774, which is controlled by the classical high-performance compute (HPC) server/cluster 872, both operating at room temperature (around 293 K). As described herein, the classical system portion interfaces with the quantum hardware to drive, control, and measure qubit operations. More particularly and as will be understood, the server/cluster 872 processes the data from the quantum hardware, including measurements from the qubits, and can also provide real-time feedback for qubit control, adjusting the parameters, including the phase shifter 706, based on the measured outcomes to optimize the quantum operations.

The microwave photon source 774 generates microwave signals that interact with the qubits. The microwave source 774 feeds microwave signals through coaxial cables into the quantum hardware. The microwave signals are controlled to ensure precise phase, amplitude, and timing, as is appropriate for quantum gate operations. The microwave photons from the microwave photon source 774 go through multiple temperature stages to reach the flux qubits (e.g., 992) in the dilution refrigerator 993.

At each stage, along with the reducing temperature, the microwave signal is heavily attenuated as qubits are provided very low-power microwave photons. Note that the HPC server/cluster 872 can control operation of the photon source 774 in terms of pulses, e.g., the sequence of pulses, the width and voltage of the pulses and the like can be controlled by the classical server/cluster 872; any amount of gates can be applied to the qubit, to control the qubit and configure the qubit, including as described herein.

A qubit bias control component (block 880, FIG. 8) provides precise magnetic flux control to the qubits. Adjusting the magnetic flux through the superconducting loops facilitates fine tuning of the qubit states. This control system operates at room temperature but communicates with the cryogenic quantum hardware through superconducting lines. The qubit bias control can be in the form of a constant voltage or current to adjust the energy levels of the qubit, and can be provided from the classical HPC server/cluster 872. A change in the magnetic flux in the qubit 992 (FIG. 9, after absorption of a photon) induces a change in the mutual flux coupling (M1) with an RF-SQUID 994, which in general acts as a detector controlled by the server/cluster 872, e.g., via a digital-to-analog converter 882. The RF-SQUID 994 includes a superconducting loop across a Josephson Junction (JJ) characterized by its critical current (IC), capacitance (C), and shunt resistance (R).

Note that in general, the digital-to-analog converter (DAC) along with an analog-to-digital converter (ADC) 883 translates between the digital signals used for classical computation and the analog signals used in the quantum hardware. The DAC 882 generates precise analog control signals for driving qubit operations, while the ADC 883 digitizes the analog signals received from the qubit measurement. These converters operate at room temperature.

To register signals in RF-SQUIDs, a readout resonator/LC (inductor-capacitor) tank circuit 994 is used, including an inductor (LT) and a capacitor (CT), which together oscillate at a natural frequency ω_{T}/2 π=1/2π\sqrt{(L_{T}−C_{T})}. The resonator 996 is designed to be sensitive to small changes in magnetic flux, mutually coupled (M2) to the RF-SQUID 994, as appropriate for detecting photon interactions with the qubit. An external pumping current I_{rf} sin (ωₚt) is provided (via labeled circle “G”) from a detector/generator 884 (FIG. 8) at frequency Ω/2π, which is very close to the natural frequency of the LC tank circuit resonator 996 (ω_{P}−ω_{T})/ω_{T}<<1 and quality factor Q>>1. The current/voltage bias (block 106) to the RF-SQUID 994 is very accurate to not (inadvertently) operate the RF-SQUID 994 in non-hysteresis mode.

Note that FIG. 9 only shows components for two RF-SQUIDS/qubits, however any practical number may be present in a given quantum computing configuration. Further note that the resonator 996 can obtain a control signal, and because any voltage generates the magnetic flux, a qubit state change will occur, as the generated magnetic flux will break the entanglement, or it will collapse the qubit; the system can read that what was the recent data, such as how much frequency changed in the resonator 996.

The output from the LC tank/resonator 996 is very weak, and hence is amplified (signal amplifier 996) and provided to the detector 884 (FIG. 8), which further performs threshold filtering (block 885) to quantize the state of the qubit, and provides the transistor-transistor logic (TTL) trigger (block 886) to the classical server/cluster 872. In general, threshold filtering component, block 885, along with the detector 884, are part of the classical control system and fed to the PCIe interface, and are responsible for analyzing the output from the quantum hardware. The signals are passed through the threshold filter to remove noise and isolate the meaningful quantum information. The detector 884 then extracts the final measurement results from the filtered signals. The TTL trigger 886 is used for synchronizing operations within the classical system and with the quantum hardware. Precise timing of signals is used in quantum systems, and the TTL trigger 886 ensures that operations such as qubit state initialization, manipulation, and readout are synchronized.

To ensure accurate control, a PCIe card interface-based digital source measure unit (SMU) 888 can be used, such as a high-performance SMU that is commercially available. In general, a digital source measure unit (SMU) 888 provides precise voltage or current control for various elements in the quantum system. The SMU 888 ensures that bias voltages and other control parameters are stable, which maintains qubit fidelity. A high-performance PXI-based SMU (PCI eXtensions for Instrumentation) provides fast, precise dynamic measurements from DC to a 20 μs pulse, with outputs up to 210 V/315 mA, 10 femtoampere (fA) resolution, and the lowest source noise.

Similarly, a commercially available PXI-based digital-to-analog converter (DAC) 882 can be used, such as one that features sixteen simultaneous channels capable of supplying stimulus waveforms with output voltages ranging from 0V to +30V, and output currents from 0 mA to +20 mA. In one implementation, both the SMU 888 and DAC 882 are compatible with PCIe interfaces and can be housed in a PXI chassis, which saves rack space and reduces maintenance cost. Also shown in FIG. 8 is the analog-to-digital converter (ADC) 883 coupled to the classical server/cluster 872 and a number of sensors (the small circles at various tap points in FIG. 9, corresponding to the circled labels D, E, G, I and J).

To summarize, in one example implementation, the digital SMU 888 can control a phase shifter (q) 706(FIGS. 7-9) that can apply a phase shift to a qubit. Phase information (block 889, FIG. 8) can be provided to the classical server/cluster 872. Such phase information allows real-time phase tuning and repeated measurements to ensure accurate quantum state tracking and error correction, e.g., if small phase deviations are detected between the applied phase and the measured phase following execution of one or more operations on the qubit as described herein, the phase can be adjusted and the operations reattempted and remeasured.

Thus, as generally represented in FIG. 8, hardware for control and readout can, for example, include one or more advanced source measure units (SMUs) and analog-to-digital converters (ADCs), which can be managed more efficiently with classical systems, thereby reducing the number of physical components and vendor equipment otherwise needed. Such a hybrid system can be designed modularly, where each module, including multiple qubits and their respective control/readout lines, can be independently managed by one or more classical processors. Such modularity simplifies system scaling, allowing new modules to be added without redesigning the entire control infrastructure.

The technology described herein leverages the precise classical control of the qubit control and measurement operations. For example, a classical high-performance computing server (or cluster of such servers) with peripheral component interconnect express (PCIe-based) or the like control can use a source measure unit (SMU) for quantum computers with some practical number (e.g., one the order of dozens) of qubits, including to apply controlled phase shift and controlled rotation to a qubit.

Further, the technology described herein controls the qubit readout circuit using a source measure unit and digital-to-analog converter; this can provide ultra-precise control of readouts with ultra-low signals. The hybrid classical-quantum technology described herein is, in part, directed to recording a photon-induced transition in a flux qubit, for example. Note however that photons/flux qubits are only examples, as indeed, the technology described herein is agnostic to any particular type of qubit, and further, that probe signals other than those based on microwave photons can be used, as appropriate for a given type of qubit.

Further, in one or more example implementations, a phase shifter can be designed and monolithically integrated with a superconducting chip that integrates the qubits. FIG. 10 is a block diagram representation of an example quantum processor measurement and control setup/system 1000 including a measurement and control setup for a superconducting quantum computing chip 1002 near the base plate of a dilution refrigerator 1003, on the order of 2-10 Kelvin (mK). Some number of qubits 1006(1)-1006(n) (four are depicted, but any practical number may be present) are fabricated on the superconducting quantum computing chip 1002, along with a monolithically integrated phase shifter (q) 1006.

Also shown in FIG. 10 as part of the qubit measuring portion are circulators 1008 and 1010, a Josephson parametric amplifier (JPA) 1012, an isolator 1014 and a high electron mobility transistor (HEMT) G. In general, a probe signal that is a set of strongly attenuated microwave tones (<−120 dBm) is by injected via coaxial cables (depicted as unshaded cylinders) and attenuators to the qubits 1006(1)-1006(n) through the various levels of the quantum processor, resulting in a measurement signal being input via a readout line to a first port of the circulator 1008. As described herein, the circulator 1008 is configured for clockwise rotation, whereby the signal is routed to a second port (low insertion loss) and not the third port (high isolation, and coupled via resistor to ground), nor returned to the first port (low return loss). The second port is coupled to the input port of a second circulator 1010 configured for counterclockwise rotation, such that the signal is routed to at least one Josephson parametric amplifier (JPA) 1012, with the amplified measurement signal routed back to the output port of the circulator 1010 though the isolator 1014 to the HEMT G for further gain before measurement by one or more conventional RF devices (not explicitly shown). Note that the shaded cylinder shown in the measurement signal output path represents a superconducting coaxial cable. Based on the measurement results, qubit control signals can be sent to the qubits 1006(1)-1006(n).

Thus, each circulator is a nonreciprocal three-port device that allows signals to travel in only one predetermined direction among its three ports, whereby the qubit readout line uses such circulators 1008 and 1010 to provide isolation between different components so as to maintain the fidelity of the qubit readout. By isolating different parts of the readout circuit, circulators help in reducing noise that could otherwise affect the qubit's state and/or the accuracy of the readout. Multiple circulators are used in the quantum computing setup, ensuring that signals are correctly channeled to the appropriate destinations as shown in FIG. 10.

To summarize FIG. 10, the state of the superconducting qubits is probed, and the readout involves amplifying and delivering the measured result back to room temperature. The weak output signal from a qubit is amplified using one or more superconducting parametric amplifiers, such as Josephson parametric amplifiers (JPA), operating at 10 mK and semiconductor high electron mobility transistor (HEMT) amplifiers operating at 4 K. The RF circulators are used to protect the quantum circuit from reflections and noise; the probing, control, and readout of qubit systems involves a large amount of microwave hardware.

One or more example implementations and embodiments can be embodied in a device, such as described and represented herein. The device can include a superconducting phase shifter. The superconducting phase shifter can include an input port coupled to a microwave signal source, and an output port coupled to a qubit chain of a quantum computing system. The superconducting phase shifter can include a hybrid coupler, which can include a first port coupled to the input port, a second port coupled to a first reflective load, the first reflective load including a first capacitor and a first microstrip inductor having a first variable inductance, a third port coupled to a second reflective load, the second reflective load including a second capacitor, and a second microstrip inductor having a second variable inductance, and a fourth port coupled to the output port. The superconducting phase shifter can include a first radio frequency-superconducting quantum interference device (RF-SQUID) set having a third variable inductance, the first RF-SQUID set inductively coupled to a first direct current (DC) control line, and inductively coupled to the first inductor. The superconducting phase shifter can include a second RF-SQUID set having a fourth variable inductance, the second RF-SQUID set inductively coupled to a second DC control line, and inductively coupled to the second inductor. The hybrid coupler divides a microwave signal from the microwave signal source into a first phase-shifted microwave signal that is reflected by the first reflective load as a reflected third phase-shifted microwave signal, and into a second phase-shifted microwave signal that is reflected by the second reflective load as a reflected fourth phase-shifted microwave signal. A first controlled current level applied to the first DC control line determines the third variable inductance of the first RF-SQUID set, to determine the first variable inductance of the first inductor, resulting in a third phase shift of the reflected third phase-shifted microwave signal. A second controlled current level applied to the second DC control line determines the fourth variable inductance of the second RF-SQUID set, to determine the second variable inductance of the second inductor, resulting in a fourth phase shift of the reflected fourth phase-shifted microwave signal. The reflected third phase-shifted microwave signal and the reflected fourth phase-shifted microwave signal constructively interfere at the fourth port to output a phase-shifted instance of the microwave signal to the qubit chain via the output port, the phase-shifted instance of the microwave signal having a phase shift based on the first controlled current level and the second controlled current level.

The hybrid coupler can include a quadrature coupler that divides the microwave signal into the first phase-shifted microwave signal, and the second phase-shifted microwave signal that can be ninety degrees phase shifted relative to the first phase-shifted microwave signal.

The first capacitor of the first reflective load can include a metal-insulator-metal capacitor, and the first inductor of the first reflective load can include a microstrip inductor.

The hybrid coupler can include respective parallel coupled lines, and respective crossovers routed through respective superconducting layers using respective inter-layer vias.

The respective inter-layer vias comprise a first superconducting bridge above a first parallel coupled line of the respective parallel coupled lines, and a second superconducting bridge below a second parallel coupled line of the respective parallel coupled lines.

The respective parallel coupled lines can be configured in a meandering pattern.

The device further can include a current limiting device coupled to the first DC control line to prevent the first current level from exceeding a defined current level. The current limiting device can be monolithically integrated into the device. The first DC control line can be coupled at a first end to a voltage terminal for application of the first controlled current level to the first DC control line, and at a second end to ground through the current limiting device.

The superconducting phase shifter can be monolithically integrated onto qubit chip that integrates at least part of the qubit chain.

The superconducting phase shifter can be deployed within a dilution refrigerator at a temperature level of about ten milli-Kelvin or below.

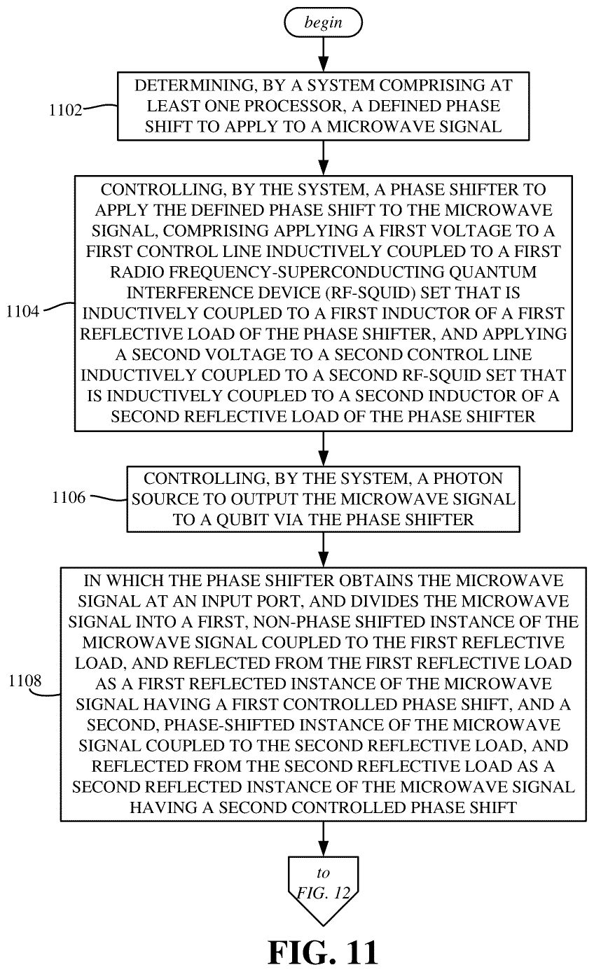

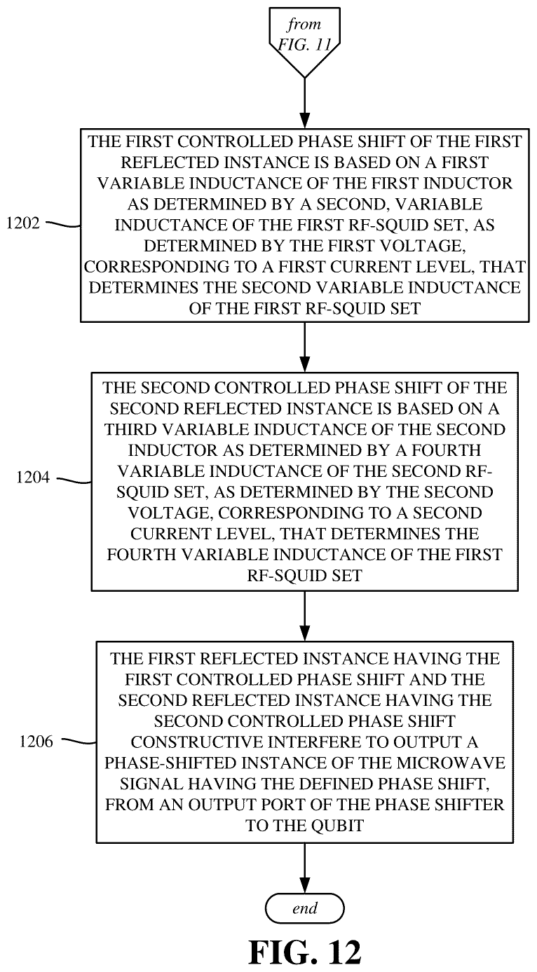

One or more example implementations and embodiments, such as corresponding to example operations of a method, can be represented in FIGS. 11 and 12. Example operation 1102 of FIG. 11 represents determining, by a system comprising at least one processor, a defined phase shift to apply to a microwave signal. Example operation 1104 of FIG. 11 represents controlling, by the system, a phase shifter to apply the defined phase shift to the microwave signal, comprising applying a first voltage to a first control line inductively coupled to a first radio frequency-superconducting quantum interference device (RF-SQUID) set that can be inductively coupled to a first inductor of a first reflective load of the phase shifter, and applying a second voltage to a second control line inductively coupled to a second RF-SQUID set that can be inductively coupled to a second inductor of a second reflective load of the phase shifter. Example operation 1106 of FIG. 11 represents controlling, by the system, a photon source to output the microwave signal to a qubit via the phase shifter. As represented in the example block 1108, the phase shifter obtains the microwave signal at an input port, and divides the microwave signal into a first, non-phase shifted instance of the microwave signal coupled to the first reflective load, and reflected from the first reflective load as a first reflected instance of the microwave signal having a first controlled phase shift, and a second, phase-shifted instance of the microwave signal coupled to the second reflective load, and reflected from the second reflective load as a second reflected instance of the microwave signal having a second controlled phase shift. Continuing at FIG. 12, example block 1202 of FIG. 12 represents that the first controlled phase shift of the first reflected instance can be based on a first variable inductance of the first inductor as determined by a second, variable inductance of the first RF-SQUID set, as determined by the first voltage, corresponding to a first current level, that determines the second variable inductance of the first RF-SQUID set. Example block 1204 represents that the second controlled phase shift of the second reflected instance can be based on a third variable inductance of the second inductor as determined by a fourth variable inductance of the second RF-SQUID set, as determined by the second voltage, corresponding to a second current level, that determines the fourth variable inductance of the first RF-SQUID set. Example block 1206 represents that the first reflected instance having the first controlled phase shift and the second reflected instance having the second controlled phase shift constructively interfere to output a phase-shifted instance of the microwave signal having the defined phase shift, from an output port of the phase shifter to the qubit.

Further operations can include obtaining, by the system, feedback information representative of qubit state data detected in response to interaction of the qubit with the phase-shifted instance of the microwave signal.

The microwave signal can be a first microwave signal, the defined phase shift can be a first defined phase shift, and further operations can include determining, by the system, a second defined phase shift to apply to a second microwave signal based on the feedback information, controlling, by the system, the phase shifter to apply the second defined phase shift to the microwave signal, comprising applying a third voltage to the first control line, and applying a fourth voltage to the second control line, and controlling, by the system, a photon source to output a second microwave signal to the qubit via the phase shifter.

The phase shifter can divide the microwave signal into the first, non-phase shifted instance of the microwave signal, and the second, phase-shifted instance of the microwave signal via a quadrature coupler that phase shifts the second, phase-shifted instance of the microwave signal ninety degrees relative to the first, non-phase-shifted instance of the microwave signal.

One or more example implementations and embodiments can be embodied in a system, such as described and represented herein. The system can include a computing device, a microwave photon source controlled by the computing device, and a superconducting phase shifter coupled to the microwave photon source, and controlled by the computing device. The superconducting phase shifter can include a first radio frequency-superconducting quantum interference device (RF-SQUID) set inductively coupled to a first control line, in which a first controlled current level in the first control line, determined by the computing device, determines a first inductance of the first RF-SQUID set, and a second RF-SQUID set inductively coupled to a second control line, in which a second controlled current level in the second control line, determined by the computing device, determines a second inductance of the second RF-SQUID set. The superconducting phase shifter can include a first reflective load that includes a first inductor inductively coupled to the first RF-SQUID set, in which the first inductance of the first RF-SQUID set determines a third inductance of the first inductor, and a second reflective load that includes a second inductor inductively coupled to the second RF-SQUID set, in which the second inductance of the second RF-SQUID set determines a fourth inductance of the second inductor. The superconducting phase shifter can include a quadrature coupler that divides a microwave signal obtained from the microwave photon source into a non-phase-shifted instance of the microwave signal that can be coupled via the hybrid coupler to the first reflective load, and into a ninety degree phase phase-shifted instance of the microwave signal that can be coupled via the quadrature coupler to the second reflective load. The computing device controls the first controlled current level and the second controlled current level, and controls the microwave photon source to output the microwave signal to the hybrid coupler of the superconducting phase shifter. The first reflective load reflects the non-phase-shifted microwave signal as a first reflected phase-shifted microwave signal having a first phase shift based on the third inductance, and the second reflective load reflects the phase-shifted microwave signal as a second reflected phase-shifted microwave signal having a second phase shift based on the fourth inductance. The first reflected phase-shifted microwave signal and the second reflected phase-shifted microwave signal constructively interfere to output a phase-shifted instance of the microwave signal having a defined phase shift based on the first controlled current level and the second controlled current level.

The superconducting phase shifter can be monolithically integrated with a qubit chip that integrates a qubit, and the superconducting phase shifter can output the phase-shifted instance of the microwave signal to the qubit for interaction with the qubit.

The phase-shifted instance can be a first phase shifted instance of a first microwave signal, the defined phase shift can be a first defined phase shift, and the computing device can obtain feedback information based on the interaction of the qubit with the first phase-shifted instance of the microwave signal, and based on the feedback, can change the first controlled current level to a third controlled current level, and can change the second controlled current level to a fourth controlled current level, to output a second phase-shifted instance of a second microwave signal having a second defined phase shift based on the third controlled current level and the fourth controlled current level.

The system further can include a current limiting device coupled to the first DC control line to prevent the first current level from exceeding a defined current level; the current limiting device can be monolithically integrated with the superconducting phase shifter.

The superconducting phase shifter can be deployed within a dilution refrigerator at a temperature level of about ten milli-Kelvin or below.

As can be seen, the technology described herein includes a phase shifter operating at cryogenic temperatures, which minimizes thermal noise and allows precise phase control for quantum gate operations. The phase shifter can be monolithically integrated onto the same chip as the qubits, eliminating the need for interconnects and ensuring ultra-low signal losses, improving upon the limitations of traditional phase shifters.

As set forth herein, traditional quantum systems are particularly vulnerable to phase noise, resulting in decoherence and reduced gate fidelity. As quantum operations require long periods of coherence, phase errors introduced by thermal noise or environmental factors can accumulate, compromising the effectiveness of quantum gate operations. To mitigate this, the phase shifter can be dynamically controlled in real time by a classical computing device-based monitoring system, to ensure that the signals interacting with the qubits are properly aligned and phase controlled. Any phase errors or noise deviations are detected by the computing device, which adjusts the phase shifter in real time to maintain optimal signal alignment, significantly improving the performance and stability of quantum computations.

Unlike existing phase shifters, the technology described herein includes RF-SQUIDs, which allows for real-time, precise control of phase shifts by dynamically adjusting the magnetic flux, providing the high precision and stability needed for various quantum operations. The use of RF-SQUIDs to achieve phase tuning tends to be robust against external perturbations. The closed-loop structure of the RF-SQUID, combined with the ability to modulate the loop's inductance, provides a stable platform for phase shifting, as employed in a reflective-type phase shifter topology to achieve precise phase control.

As a further benefit, the phase shifter design can be implemented with a very small physical footprint and cryogenic compatibility, making it highly suitable for compact and dense architectures of future multiqubit systems. The phase shifter can be based on a multilayer fabrication process with interlayer vias, ensuring large isolation between signal paths, which minimizes interference and crosstalk.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit, and scope in accordance with the appended claims.

What is claimed is:

1. A device, comprising:
a superconducting phase shifter, comprising:
an input port coupled to a microwave signal source, and an output port coupled to a qubit chain of a quantum computing system;
a hybrid coupler comprising:
a first port coupled to the input port,
a second port coupled to a first reflective load, the first reflective load comprising a first capacitor and a first microstrip inductor having a first variable inductance,
a third port coupled to a second reflective load, the second reflective load comprising a second capacitor, and a second microstrip inductor having a second variable inductance, and
a fourth port coupled to the output port;
a first radio frequency-superconducting quantum interference device (RF-SQUID) set having a third variable inductance, the first RF-SQUID set inductively coupled to a first direct current (DC) control line, and inductively coupled to the first inductor; and
a second RF-SQUID set having a fourth variable inductance, the second RF-SQUID set inductively coupled to a second DC control line, and inductively coupled to the second inductor,
wherein the hybrid coupler divides a microwave signal from the microwave signal source into a first phase-shifted microwave signal that is reflected by the first reflective load as a reflected third phase-shifted microwave signal, and into a second phase-shifted microwave signal that is reflected by the second reflective load as a reflected fourth phase-shifted microwave signal,
wherein a first controlled current level applied to the first DC control line determines the third variable inductance of the first RF-SQUID set, to determine the first variable inductance of the first inductor, resulting in a third phase shift of the reflected third phase-shifted microwave signal,
wherein a second controlled current level applied to the second DC control line determines the fourth variable inductance of the second RF-SQUID set, to determine the second variable inductance of the second inductor, resulting in a fourth phase shift of the reflected fourth phase-shifted microwave signal, and
wherein the reflected third phase-shifted microwave signal and the reflected fourth phase-shifted microwave signal constructively interfere at the fourth port to output a phase-shifted instance of the microwave signal to the qubit chain via the output port, the phase-shifted instance of the microwave signal having a phase shift based on the first controlled current level and the second controlled current level.

2. The device of claim 1, wherein the hybrid coupler comprises a quadrature coupler that divides the microwave signal into the first phase-shifted microwave signal, and the second phase-shifted microwave signal that is ninety degrees phase shifted relative to the first phase-shifted microwave signal.

3. The device of claim 1, wherein the first capacitor of the first reflective load comprises a metal-insulator-metal capacitor, and wherein the first inductor of the first reflective load comprises a microstrip inductor.

4. The device of claim 1, wherein the hybrid coupler comprises respective parallel coupled lines, and respective crossovers routed through respective superconducting layers using respective inter-layer vias.

5. The device of claim 4, wherein the respective inter-layer vias comprise a first superconducting bridge above a first parallel coupled line of the respective parallel coupled lines, and a second superconducting bridge below a second parallel coupled line of the respective parallel coupled lines.

6. The device of claim 4, wherein the respective parallel coupled lines are configured in a meandering pattern.

7. The device of claim 1, further comprising a current limiting device coupled to the first DC control line to prevent the first current level from exceeding a defined current level.

8. The device of claim 7, wherein the current limiting device is monolithically integrated into the device.

9. The device of claim 8, wherein the first DC control line is coupled at a first end to a voltage terminal for application of the first controlled current level to the first DC control line, and at a second end to ground through the current limiting device.

10. The device of claim 1, wherein the superconducting phase shifter is monolithically integrated onto qubit chip that integrates at least part of the qubit chain.

11. The device of claim 1, wherein the superconducting phase shifter is deployed within a dilution refrigerator at a temperature level of about ten milli-Kelvin or below.

12. A method, comprising:
determining, by a system comprising at least one processor, a defined phase shift to apply to a microwave signal;
controlling, by the system, a phase shifter to apply the defined phase shift to the microwave signal, comprising applying a first voltage to a first control line inductively coupled to a first radio frequency-superconducting quantum interference device (RF-SQUID) set that is inductively coupled to a first inductor of a first reflective load of the phase shifter, and applying a second voltage to a second control line inductively coupled to a second RF-SQUID set that is inductively coupled to a second inductor of a second reflective load of the phase shifter; and
controlling, by the system, a photon source to output the microwave signal to a qubit via the phase shifter,
wherein the phase shifter obtains the microwave signal at an input port, and divides the microwave signal into a first, non-phase shifted instance of the microwave signal coupled to the first reflective load, and reflected from the first reflective load as a first reflected instance of the microwave signal having a first controlled phase shift, and a second, phase-shifted instance of the microwave signal coupled to the second reflective load, and reflected from the second reflective load as a second reflected instance of the microwave signal having a second controlled phase shift,
wherein the first controlled phase shift of the first reflected instance is based on a first variable inductance of the first inductor as determined by a second, variable inductance of the first RF-SQUID set, as determined by the first voltage, corresponding to a first current level, that determines the second variable inductance of the first RF-SQUID set,
wherein the second controlled phase shift of the second reflected instance is based on a third variable inductance of the second inductor as determined by a fourth variable inductance of the second RF-SQUID set, as determined by the second voltage, corresponding to a second current level, that determines the fourth variable inductance of the first RF-SQUID set, and
wherein the first reflected instance having the first controlled phase shift and the second reflected instance having the second controlled phase shift constructively interfere to output a phase-shifted instance of the microwave signal having the defined phase shift, from an output port of the phase shifter to the qubit.

13. The method of claim 12, further comprising obtaining, by the system, feedback information representative of qubit state data detected in response to interaction of the qubit with the phase-shifted instance of the microwave signal.

14. The method of claim 13, wherein the microwave signal is a first microwave signal, wherein the defined phase shift is a first defined phase shift, and further comprising:
determining, by the system, a second defined phase shift to apply to a second microwave signal based on the feedback information;
controlling, by the system, the phase shifter to apply the second defined phase shift to the microwave signal, comprising applying a third voltage to the first control line, and applying a fourth voltage to the second control line; and
controlling, by the system, a photon source to output a second microwave signal to the qubit via the phase shifter.

15. The method of claim 13, wherein the phase shifter divides the microwave signal into the first, non-phase shifted instance of the microwave signal, and the second, phase-shifted instance of the microwave signal via a quadrature coupler that phase shifts the second, phase-shifted instance of the microwave signal ninety degrees relative to the first, non-phase-shifted instance of the microwave signal.

16. A system, comprising:
a computing device;
a microwave photon source controlled by the computing device;
a superconducting phase shifter coupled to the microwave photon source, and controlled by the computing device, the superconducting phase shifter comprising:
a first radio frequency-superconducting quantum interference device (RF-SQUID) set inductively coupled to a first control line, wherein a first controlled current level in the first control line, determined by the computing device, determines a first inductance of the first RF-SQUID set;
a second RF-SQUID set inductively coupled to a second control line, wherein a second controlled current level in the second control line, determined by the computing device, determines a second inductance of the second RF-SQUID set;
a first reflective load comprising a first inductor inductively coupled to the first RF-SQUID set, wherein the first inductance of the first RF-SQUID set determines a third inductance of the first inductor;
a second reflective load comprising a second inductor inductively coupled to the second RF-SQUID set, wherein the second inductance of the second RF-SQUID set determines a fourth inductance of the second inductor; and
a quadrature coupler that divides a microwave signal obtained from the microwave photon source into a non-phase-shifted instance of the microwave signal that is coupled via the hybrid coupler to the first reflective load, and into a ninety degree phase phase-shifted instance of the microwave signal that is coupled via the quadrature coupler to the second reflective load,
wherein the computing device:
controls the first controlled current level and the second controlled current level, and
controls the microwave photon source to output the microwave signal to the hybrid coupler of the superconducting phase shifter,
wherein the first reflective load reflects the non-phase-shifted microwave signal as a first reflected phase-shifted microwave signal having a first phase shift based on the third inductance, and the second reflective load reflects the phase-shifted microwave signal as a second reflected phase-shifted microwave signal having a second phase shift based on the fourth inductance, and
wherein the first reflected phase-shifted microwave signal and the second reflected phase-shifted microwave signal constructively interfere to output a phase-shifted instance of the microwave signal having a defined phase shift based on the first controlled current level and the second controlled current level.

17. The system of claim 16, wherein the superconducting phase shifter is monolithically integrated with a qubit chip that integrates a qubit, and wherein the superconducting phase shifter outputs the phase-shifted instance of the microwave signal to the qubit for interaction with the qubit.

18. The system of claim 16, wherein the phase-shifted instance is a first phase shifted instance of a first microwave signal, wherein the defined phase shift is a first defined phase shift, and wherein the computing device obtains feedback information based on the interaction of the qubit with the first phase-shifted instance of the microwave signal, and based on the feedback, changes the first controlled current level to a third controlled current level, and changes the second controlled current level to a fourth controlled current level, to output a second phase-shifted instance of a second microwave signal having a second defined phase shift based on the third controlled current level and the fourth controlled current level.

19. The system of claim 16, further comprising a current limiting device coupled to the first DC control line to prevent the first current level from exceeding a defined current level, wherein the current limiting device is monolithically integrated with the superconducting phase shifter.

20. The system of claim 1, wherein the superconducting phase shifter is deployed within a dilution refrigerator at a temperature level of about ten milli-Kelvin or below.
